(19) United States
(12) Patent Application Publication
(10) Pub. No.: US 2018/0120382 A1
(43) Pub. Date: May 3, 2018

(54) BATTERY CAPACITY ESTIMATION FOR A BATTERY PACK

(71) Applicant: MOTOROLA SOLUTIONS, INC., Chicago, IL (US)

(72) Inventor: Jeffrey L. Cutcher, Plantation, FL (US)

(21) Appl. No.: 15/336,643

(22) Filed: Oct. 27, 2016

(51) Int. Cl. G01R 31/36

(52) U.S. Cl. CPC G01R 31/3651; G01R 31/3679; G01R 31/3655; G01R 31/3637

(57) ABSTRACT

Methods and devices for battery capacity estimation. One embodiment provides a method for battery capacity estimation for a battery pack of an electronic device, the battery pack including a battery and a writeable memory. The method includes reading an accumulated charge count from the writeable memory and detecting a connection of the battery to a charger. The method also includes determining an initial state of charge of the battery when the connection of the battery to the charger is detected and determining a second state of charge of the battery. The method further includes determining a charge count change based on the initial state of charge and the second state of charge and determining a new accumulated charge count based on the charge count change and the accumulated charge count. The method also includes writing the new accumulated charge count to the writeable memory.

### BACKGROUND OF THE INVENTION

Electronic devices such as portable two-way radios are frequently used over a long period of time without charging. A user, for example, a public safety officer, may carry multiple battery packs to swap-out a discharged battery pack for a fully charged battery pack. Users often depend on the battery capacity estimation of the electronic device in swapping out the battery packs. However, battery capacity degrades over time. As a consequence, the electronic device may not accurately estimate the remaining capacity in a battery pack.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a diagram of an electronic device with a battery pack in accordance with some embodiments.

FIG. 2 is a diagram of the electronic device of FIG. 1 in accordance with some embodiments.

FIG. 3 is a diagram of the battery pack of FIG. 1 in accordance with some embodiments.

FIG. 4 illustrates a look-up table in accordance with some embodiments.

FIG. 5 is a flowchart of a method for battery capacity estimation in accordance with some embodiments.

FIG. 6 is a flowchart of a method for battery capacity estimation in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments so as not to obscure the disclosure with details that will be readily apparent to those of ordinary skill in the art having the benefit of the description herein.

### DETAILED DESCRIPTION OF THE INVENTION

One embodiment provides an electronic device including a battery pack having a battery and a writeable memory. The writeable memory includes an accumulated charge count of the battery. The electronic device also includes an electronic processor configured to communicate with the memory. The electronic processor is also configured to read the accumulated charge count from the writeable memory and detect a connection of the battery to a charger. The electronic processor is further configured to determine an initial state of charge of the battery when the connection to the charger is detected and determine a second state of charge of the battery. The electronic processor is also configured to determine a charge count change based on the initial state of charge and the second state of charge and determine a new accumulated charge count based on the accumulated charge count and the charge count change. The electronic processor writes the new accumulated charge count to the writeable memory.

Another embodiment provides a method for battery capacity estimation for a battery pack of an electronic device, the battery pack including a battery and a writeable memory. The method includes reading, with an electronic processor, an accumulated charge count from the writeable memory and detecting, with the electronic processor, a connection to of the battery to a charger. The method also includes determining, with the electronic processor, an initial state of charge of the battery when the connection to of the battery to the charger is detected and determining, with the electronic processor, a second state of charge of the battery. The method further includes determining, with the electronic processor, a charge count change based on the initial state of charge and the second state of charge and determining, with the electronic processor, a new accumulated charge count based on the charge count change and the accumulated charge count. The method also includes writing, with the electronic processor, the new accumulated charge count to the writeable memory.

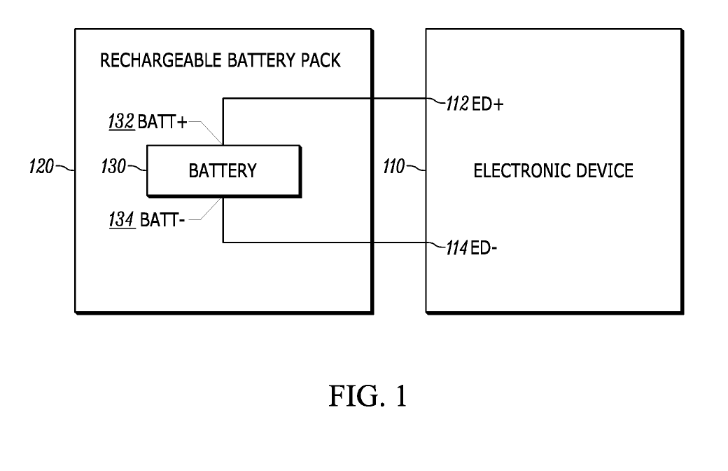

FIG. 1 is a diagram of one embodiment of an electronic device 110. The electronic device 110 may be, for example, a two-way radio, a mobile device, a tablet computer, a personal computer, and the like that is powered by a rechargeable battery pack 120. The rechargeable battery pack 120 includes at least one battery 130. In some embodiments, the electronic device 110 may also be a battery charger used to charge, for example, batteries including the one or more batteries in the rechargeable battery pack 120. In some embodiments, the rechargeable battery pack 120 is included in the electronic device 110. In other embodiments, the rechargeable battery pack 120 is a removable battery pack.

The battery 130 includes a positive terminal 132 connected to a positive terminal 112 of the electronic device 110. The battery 130 includes a negative terminal 134 connected to a negative terminal 114 of the electronic device 110. The battery 130 may be, for example, a Nickel-Cadmium (NiCd) battery, a Lithium-ion (Li-ion) battery, or the like.

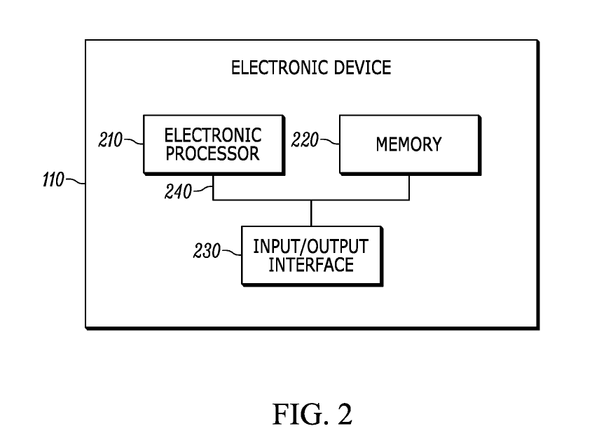

FIG. 2 is a block diagram of one embodiment of the electronic device 110. In the example illustrated, the electronic device 110 includes an electronic processor 210, a memory 220, and an input/output interface 230. The electronic processor 210, the memory 220, and the input/output interface 230 communicate over one or more control and/or data buses (for example, a communication bus 240). FIG. 2 illustrates only one exemplary embodiment of an electronic device 110. The electronic device 110 may include more or fewer components and may perform functions other than those explicitly described herein.

In some embodiments, the electronic processor 210 is implemented as a microprocessor with separate memory, such as the memory 220. In other embodiments, the electronic processor 210 may be implemented as a microcontroller (with memory 220 on the same chip). In other embodiments, the electronic processor 210 may be implemented using multiple processors. In addition, the electronic processor 210 may be implemented partially or entirely as, for example, a field-programmable gate array (FPGA), and application specific integrated circuit (ASIC), and the like and the memory 220 may not be needed or be modified accordingly. In the example illustrated, the memory 220 includes non-transitory, computer-readable memory that stores instructions that are received and executed by the electronic processor 210 to carry out functionality of the electronic device 110 described herein. The memory 220 may include, for example, a program storage area and a data storage area. The program storage area and the data storage area may include combinations of different types of memory, such as read-only memory and random-access memory.

As noted above, the electronic device 110 may include the input/output interface 230. The input/output interface 230 may include one or more input mechanisms (for example, a touch screen, a keypad, a button, a knob, and the like), one or more output mechanisms (for example, a display, a printer, a speaker, and the like), or a combination thereof. The input/output interface 230 receives input from input devices actuated by a user, and provides output to output devices with which a user interacts.

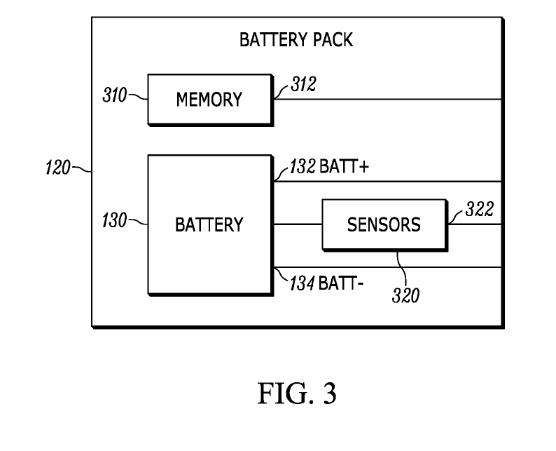

FIG. 3 is a block diagram of one embodiment of the battery pack 120. In the example illustrated, the battery pack 120 includes the battery 130, a writeable memory 310, and one or more sensors 320. FIG. 3 illustrates only one exemplary embodiment of the battery pack 120. The battery pack 120 may include more or fewer components and may perform functions other than those explicitly described herein. For example, the battery pack 120 may also include a battery electronic processor and the functionality of the electronic processor 210 described herein may be shared between the electronic processor 210 and the battery electronic processor.

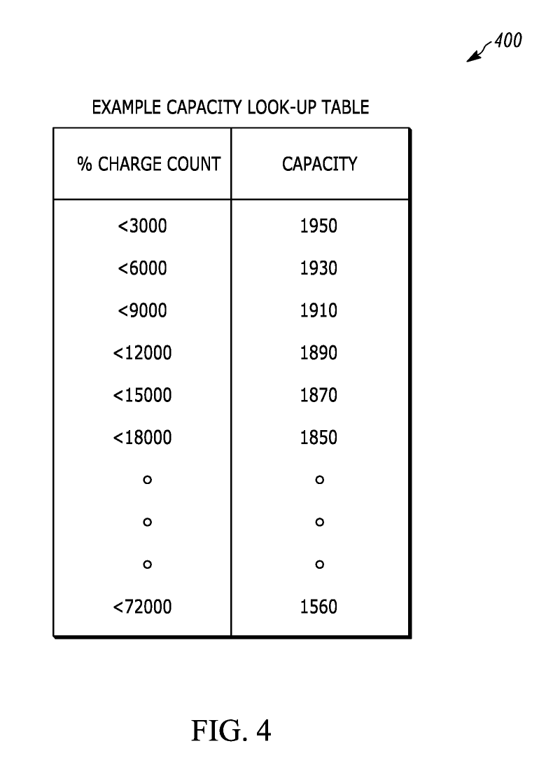

In the example illustrated in FIG. 3, the writeable memory 310 includes non-transitory memory and is capable of being written or receiving and storing information from the electronic processor 210. In one example, the writeable memory 310 is an electrically erasable programmable read only memory (EEPROM) that may be read from and written to. The writeable memory 310 may store certain information regarding the battery pack 120, for example, a model number, a battery identification number, an accumulated charge count, and the like. The writeable memory 310 also stores a look-up table 400 (shown in FIG. 4). As illustrated in FIG. 4, the look-up table 400 stores a mapping between a plurality of accumulated charge count values and a plurality of battery capacity values for the battery 130. The battery capacity may be stored in, for example, milliampere-hour units. In some embodiments, the look-up table 400 is a linear look-up table where the battery capacity values have a linear relationship with the accumulated charge count values. In some embodiments, the look-up table 400 may be a non-linear look-up table where the battery capacity values have a non-linear (for example, exponential decay, logarithmic decay, and the like) relationship with the accumulated charge count values. In other embodiments, the look-up table 400 may be a database storing a mapping between accumulated charge count, battery capacity, and other characteristics of the battery 130.

Returning to FIG. 3, the sensors 320 may include, for example, a voltage sensor, a temperature sensor, a pressure sensor, and the like. The sensors 320 measure certain characteristics of the battery 130 and communicate these characteristics to the electronic processor 210. In some embodiments, the battery pack 120 and the electronic device 110 may communicate over separate power and communication lines. For example, power terminals (for example, positive terminal 132 and negative terminal 134) of the battery pack 120 may be connected to power terminals (for example positive terminal 112 and negative terminal 114) of the electronic device 110 and communication terminals (for example, a memory terminal 312 and a sensor terminal 322) may be connected over a separate line to the electronic device 110. In other embodiments, the power terminals and the communication terminals may be connected over a single connection by, for example, a “1-Wire®” communication bus.

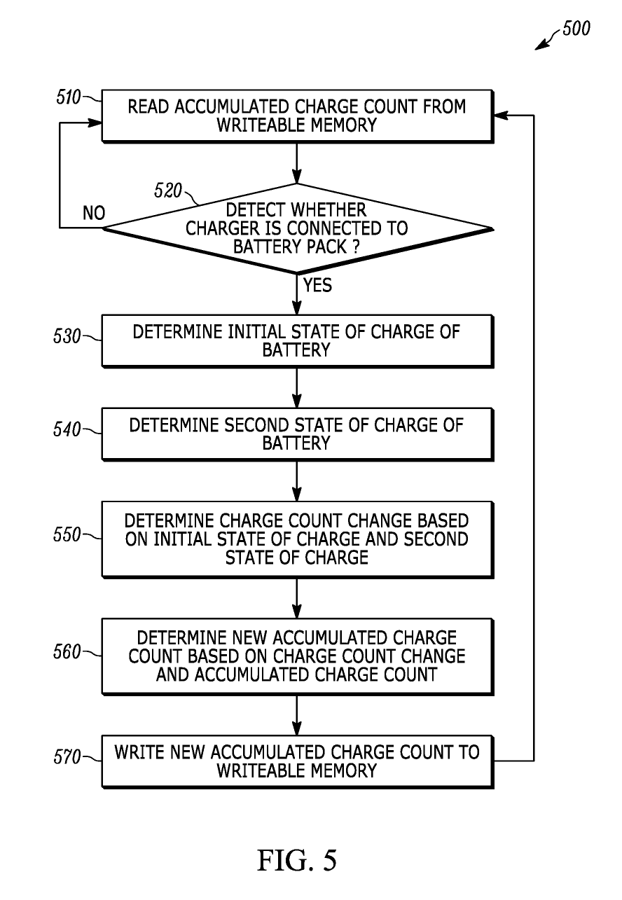

FIG. 5 is a flowchart illustrating one example method 500 for battery capacity estimation for battery pack 120 of the electronic device 110. As illustrated in FIG. 5, the method 500 includes reading, with the electronic processor 210, an accumulated charge count from the writeable memory 310 (at block 510). The accumulated charge count may be stored in the writeable memory 310 during a previous charging operation of the battery pack 120. Initially, the accumulated charge count may be zero and is stored in the writeable memory 310 during manufacturing.

The method 500 includes detecting, with the electronic processor 210, whether a charger is connected to the battery pack 120 (at block 520). In some embodiments, the electronic processor 210 may detect that a charger is connected to the battery pack 120 when the electronic processor 210 detects a current or voltage at a charging port of the electronic device 110. In some embodiments, the electronic processor 210 may detect that a charger is connected to the battery pack 120 when the sensors 320 (for example, a current sensor) indicates to the electronic processor 210 that a charging current is flowing to the battery 130. When the electronic processor 210 determines that a charger is connected to the battery pack 120, the method 500 includes determining, with the electronic processor 210, an initial state of charge of the battery 130 (at block 530). The initial state of charge of the battery 130 may be determined based on a voltage measurement of the battery 130. For example, the initial state of charge may be determined based on a voltage reading from the sensors 320 (for example, measuring voltage with a voltage sensor) after accounting for the load connected to the battery pack 120 and the internal resistance of the battery pack 120. The electronic processor 210 communicates with the sensors 320 to take the measurements of the state of charge of the battery 130. In some embodiments, the electronic processor 210 takes multiple measurements of the state of charge of the battery pack 120 (for example, a plurality of state of charge values) in a short time period and determines an average of the multiple measurements to determine an initial state of charge. The initial state of charge may be measured or determined as a percentage. For example, when the battery pack 120, is fully charged, the state of charge is “100%” and when the battery pack 120 is fully discharged, the state of charge is “0%.”

The method 500 also includes determining, with the electronic processor 210 a second state of charge of the battery 130 (at block 540). In some embodiments, the electronic processor 210 determines the second state of charge of the battery 130 when the electronic processor 210 detects that a charging operation is terminated (or termination of charging). The charging operation is terminated, for example, when the charger is disconnected from the battery 130 or when the electronic processor 210 determines that the battery 130 is fully charged. For example, the electronic processor 210 may receive an indication from the sensors 320 that the battery 130 is fully charged. The second state of charge may be determined in similar ways as described above with respect to the first state of charge. As described above, the second state of charge is measured or determined as a percentage.

The method 500 then includes determining, with the electronic processor 210, a charge count change based on the initial state of charge and the second state of charge (at block 550). In some embodiments, the charge count change may be determined by subtracting the initial state of charge from the final state of charge. For example, when a charging operation begins, the electronic processor 210 may determine that an initial state of charge of the battery 130 is “4%.” When the electronic processor 210 detects that the charging operation is terminated, the electronic processor 210 may determine that the second state of charge of the battery is, for example, “89%.” The electronic processor 210 then determines the charge count change by subtracting the initial state of charge (that is, “4%”) from the final state of charge (that is, “89%”). Therefore, the charge count change is “85,” which is “89−4.” In some embodiments, the second state of charge of the battery 130 may be determined continuously over the period of time the battery 130 is charging. For example, the electronic processor 210 may determine the second state of charge every five minutes. In this example, the electronic processor 210 may use a previous second state of charge (for example, the second state of charge determined five minutes ago) as the initial state of charge to determine the charge count change.

The method 500 determines, with the electronic processor 210, a new accumulated charge count based on the charge count change and the accumulated charge count (at block 560). In some embodiments, the new accumulated charge count may be determined by adding the charge count change to the accumulated charge count. Using the above example, the electronic processor 210 may read from the writeable memory 310 that the accumulated charge count is “100.” After the electronic processor 210 determines that the charge count change is “85” at block 550, the electronic processor 210 adds the charge count change (that is, “85”) to the accumulated charge count (that is, “100”). Therefore, the new accumulated charge count is “185,” which is “100+85.”

The method 500 includes writing, with the electronic processor 210, the new accumulated charge count to the writeable memory 310 (at block 570). The electronic processor 210 may replace the accumulated charge count read at block 510 with the new accumulated charge count. The new accumulated charge count acts as the initial accumulated charge count read at block 510 for succeeding charge operations. In public safety implementations, electronic devices 110 are used over a long period of time. As such, users of electronic devices 110 often carry multiple battery packs 120, which they switch-out often. Writing the new accumulated charge count to the writeable memory 310 of the battery pack 120 ensures that the next time the battery pack 120 is used with the electronic device 110, the electronic device 110 may update the accumulated charge count and determine the battery capacity accurately. The method 500 repeats for each charging operation.

In addition to the accumulated charge count, the writeable memory 310 may store additional charging information for the battery pack 120. In some embodiments, the writeable memory 310 may store a cumulative charge count for the battery 130. The cumulative charge count stores the number of times a charging operation was performed for the battery pack 120. The electronic processor 210 may increment the cumulative charge count when the electronic processor 210 detects that a charging operation is started or when the electronic processor 210 detects that a charging operation is terminated. In some embodiments, the writeable memory 310 may store the last few initial state of charge values determined by the electronic processor 210. For example, the writeable memory 310 may store the last five initial state of charge values that were determined by the electronic processor 210 during the last five charging operations. In these embodiments, the writeable memory 310 may also store a moving average of the initial state of charge values. The electronic processor 210 may update the values stored in the writeable memory 310 after every charging operation (that is, after completion of method 500).

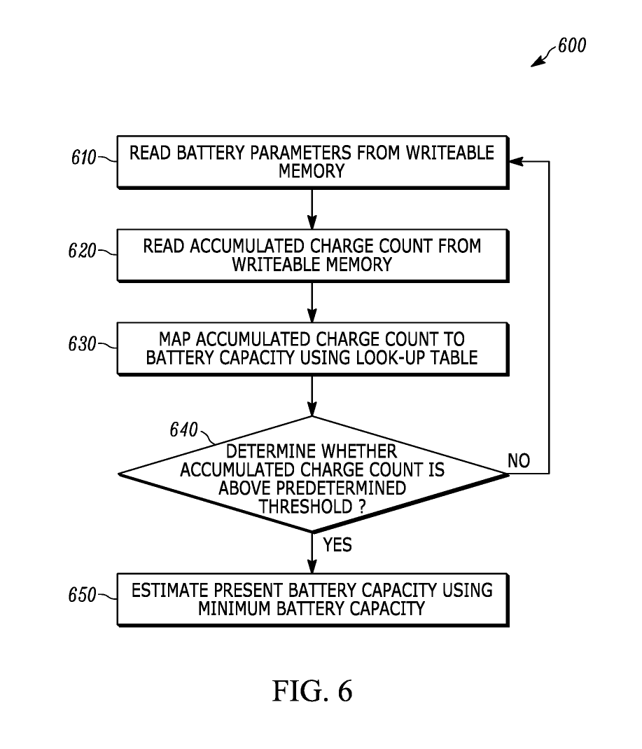

FIG. 6 is a flowchart illustrating one example method 600 for battery capacity estimation based on accumulated charge count. As illustrated in FIG. 6, the method 600 includes reading, with the electronic processor 210, battery parameters from the writeable memory 310 (at block 610). For example, the electronic processor 210 may read the battery identification information, the battery power output, the battery cumulative charge count, and the like. The method 600 also includes reading, with the electronic processor 210, the accumulated charge count from the writeable memory 310 (at block 620). As described above, the accumulated charge count may be written to the writeable memory 310 during manufacturing or during a previous charging operation.

The method 600 includes mapping, with the electronic processor 210, the accumulated charge count to a battery capacity using the look-up table 400 (at block 630). The battery capacity determined from the look-up table 400 may be the battery capacity when the battery 130 is fully charged. The electronic processor 210 may then determine the present battery capacity based on the battery capacity determined at block 630 and the current state of charge of the battery 130. For example, when the electronic processor 210 reads that the accumulated charge count is “7000,” the electronic processor 210 may determine from the look-up table 400 that the battery capacity of the battery 130 at full charge is “1910” milliampere-hours. The electronic processor 210 then determines the current state of charge of the battery pack 120 and determines the present battery capacity. For example, the electronic processor 210 may determine that the current state of charge of the battery 130 is “50%.” Therefore, the present battery capacity may be “50%” of “1910” milliampere-hours which is “955” milliampere-hours. The electronic processor 210 may output the present battery capacity on a user interface (for example, outputting via the input/output interface 230) of the electronic device 110. In some embodiments, the electronic processor 210 may write the battery capacity in the writeable memory 310.

For some battery packs 120, the battery capacity may not be reliably determined after a certain number of charge cycles or after a certain amount of accumulated charge value. For example, a battery capacity of the battery 130 may not be accurately determined after an accumulated charge count of 72000. The method 600 includes determining, with the electronic processor 210, whether the accumulated charge count is above a predetermined threshold (at block 640). For example, the electronic processor 210 may determine whether the accumulated charge count is above “72000.” In some embodiments, instead of the accumulated charge count, the electronic processor 210 may determine whether the battery capacity is below a predetermined threshold. When the accumulated charge count is above the predetermined threshold, the electronic processor 210 estimates the present battery capacity using the minimum battery capacity (at block 650). The minimum battery capacity may be set to, for example, “1560” milliampere-hour as shown in FIG. 4. In some embodiments, the electronic processor 210 may stop updating the accumulated charge count upon determining that the accumulated charge count is above the predetermined threshold. The method 600 repeats for each estimation operation when the accumulated charge count is below the predetermined threshold.

In some embodiments, the present battery capacity may be used to activate a safe shutdown feature of the battery pack 120 or the electronic device 110. The electronic processor 210 may determine whether the battery capacity is below a predetermined battery capacity threshold. When the electronic processor 210 determines that the battery capacity is below a predetermined battery capacity threshold, the electronic processor 210 may activate the safe shutdown feature. The safe shutdown feature may include, for example, running the electronic device 110 in a low-battery mode, saving unsaved data, providing an alert to a user of the electronic device 110, or the like.

Methods 500 and 600 are described with respect to systems and devices of FIGS. 1, 2, and 3. However, methods 500 and 600 may be performed with other systems and devices. In addition, the methods 500 and 600 may be modified or performed differently than the specific examples provided. The methods 500 and 600 are described as being performed by the electronic processor 210. Alternatively, the functionality provided in the methods 500 and 600 may be distributed between multiple electronic processors, for example, the electronic processor 210 and a battery electronic processor of the battery pack 120.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. An electronic device comprising:
a battery pack including a battery and a writeable memory, the writeable memory including an accumulated charge count of the battery; and
an electronic processor configured to communicate with the writeable memory and to:
read the accumulated charge count from the writeable memory
detect a connection of the battery to a charger;
determine an initial state of charge of the battery when the connection to the charger is detected;
determine a second state of charge of the battery;
determine a charge count change based on the initial state of charge and the second state of charge;
determine a new accumulated charge count based on the accumulated charge count and the charge count change; and
write the new accumulated charge count to the writeable memory.

2. The electronic device of claim 1, wherein the writeable memory includes a look-up table mapping a plurality of accumulated charge count values to a plurality of battery capacity values, and the electronic processor is further configured to:
read the new accumulated charge count from the writeable memory;
map the new accumulated charge count to a battery capacity based on the look-up table; and
output the battery capacity.

3. The electronic device of claim 2, wherein the electronic processor is further configured to write the battery capacity to the writeable memory.

4. The electronic device of claim 2, wherein the look-up table is a non-linear look-up table.

5. The electronic device of claim 2, wherein the electronic processor is further configured to:
determine a present battery capacity based on the battery capacity;
determine whether the present battery capacity is below a predetermined battery capacity threshold; and
when the present battery capacity is below the predetermined battery capacity threshold, activate a shutdown feature of the electronic device.

6. The electronic device of claim 1, further comprising a memory coupled to the electronic processor, wherein the memory stores a look-up table mapping a plurality of accumulated charge count values to a plurality of battery capacity values, the electronic processor further configured to:
read the new accumulated charge count from the writeable memory;
map the new accumulated charge count to a battery capacity based on the look-up table; and
output the battery capacity.

7. The electronic device of claim 1, wherein the battery pack comprises a removable battery pack.

8. The electronic device of claim 1, further comprising a voltage sensor coupled to the battery, wherein the electronic processor communicates with the voltage sensor to determine the initial state of charge and the second state of charge.

9. The electronic device of claim 8, wherein the initial state of charge is determined by measuring, with the voltage sensor, a plurality of state of charge values of the battery and determining an average of the plurality of state of charge values of the battery.

10. The electronic device of claim 8, wherein the second state of charge is determined by measuring, with the voltage sensor, a plurality of state of charge values of the battery and determining an average of the plurality of state of charge values of the battery.

11. The electronic device of claim 1, further comprising detecting that a charging operation is terminated, wherein the electronic processor determines the second state of charge when termination of the charging operation is detected.

12. A method for battery capacity estimation for a battery pack of an electronic device, the battery pack including a battery and a writeable memory, the method comprising:
reading, with an electronic processor, an accumulated charge count from the writeable memory;
detecting, with the electronic processor, a connection of the battery to a charger;
determining, with the electronic processor, an initial state of charge of the battery when the connection of the battery to the charger is detected;
determining, with the electronic processor, a second state of charge of the battery;
determining, with the electronic processor, a charge count change based on the initial state of charge and the second state of charge;
determining, with the electronic processor, a new accumulated charge count based on the charge count change and the accumulated charge count; and
writing, with the electronic processor, the new accumulated charge count to the writeable memory.

13. The method of claim 12, wherein the writeable memory includes a look-up table mapping a plurality of accumulated charge count values to a plurality of battery capacity values, the method further comprising:
reading the new accumulated charge count from the writeable memory;
mapping the new accumulated charge count to a battery capacity based on the look-up table; and
outputting the battery capacity.

14. The method of claim 13, further comprising writing the battery capacity to the writeable memory.

15. The method of claim 13, further comprising:
determining a present battery capacity based on the battery capacity;
determining whether the present battery capacity is below a predetermined battery capacity threshold; and
when the present battery capacity is below the predetermined battery capacity threshold, activating a shutdown feature of the electronic device.

16. The method of claim 12, further comprising a memory coupled to the electronic processor, wherein the memory stores a look-up table mapping a plurality of accumulated charge count values to a plurality of battery capacity values, the method further comprising:
reading the new accumulated charge count from the writeable memory;
mapping the new accumulated charge count to a battery capacity based on the look-up table; and
outputting the battery capacity.

17. The method of claim 12, wherein the battery pack further includes a voltage sensor coupled to the battery, the method further comprising communicating with the voltage sensor to determine the initial state of charge and the second state of charge.

18. The method of claim 17, wherein the initial state of charge is determined by measuring, with the voltage sensor, a plurality of state of charge values of the battery and determining an average of the plurality of state of charge values of the battery.

19. The method of claim 17, wherein the second state of charge is determined by measuring, with the voltage sensor, a plurality of state of charge values of the battery and determining an average of the plurality of state of charge values of the battery.

20. The method of claim 12, further comprising detecting that a charging operation is terminated, wherein determining the second state of charge of the battery includes determining the second state of charge when termination of the charging operation is detected.
